(19) United States
(12) Patent Application Publication
(10) Pub. No.: US 2016/0351688 A1
(43) Pub. Date: Dec. 1, 2016

(54) METHOD OF MANUFACTURING INSULATED GATE SWITCHING DEVICE

(71) Applicant: Toyota Jidosha Kabushiki Kaisha, Toyota-shi Aichi-ken (JP)

(72) Inventors: Satoru Kameyama, Toyota-shi Aichi-ken (JP); Shinya Iwasaki, Toyota-shi Aichi-ken (JP); Seiji Arakawa, Toyota-shi Aichi-ken (JP)

(21) Appl. No.: 15/157,967

(22) Filed: May 18, 2016

(30) Foreign Application Priority Data
May 27, 2015 (JP) 2015-107486

(51) Int. Cl. H01L 29/66; H01L 29/423; H01L 21/308; H01L 21/265; H01L 21/28

(52) U.S. Cl. CPC H01L 29/66666; H01L 21/265; H01L 21/28008; H01L 21/3085; H01L 29/4236

(57) ABSTRACT

A method of manufacturing an insulated gate switching device includes: forming a trench in a front surface of a semiconductor substrate; forming a gate insulating film in the trench; depositing an electrode layer made of semiconductor in the trench and on the front surface after forming the gate insulating film; polishing the electrode layer so as to remove a portion of the electrode layer on the front surface and expose an underlayer of the removed portion of the electrode layer; forming a cap insulating film in a surface layer of a portion of the electrode layer in the trench by heating the semiconductor substrate after exposing the underlayer; and implanting impurities from above the front surface into a range extending across the portion of the electrode layer in the trench and the semiconductor substrate.

### CROSS-REFERENCE TO RELATED APPLICATION

This application claims priority to Japanese Patent Application No. 2015-107486 filed on May 27, 2015, the entire contents of which are hereby incorporated by reference into the present application.

### TECHNICAL FIELD

The technique disclosed herein relates to a method of manufacturing an insulated gate switching device.

### BACKGROUND ART

An insulated gate switching device, for example, an IGBT (Insulated Gate Bipolar Transistor), MOSFET (Metal Oxide Silicon Field Effect Transistor), etc. provided with gate electrodes arranged within trenches is known. As a method of manufacturing this type of insulated gate switching device, there is a technique which forms an n-type or p-type diffusion layer in a semiconductor substrate, forms trenches so as to pierce through the formed diffusion layer, and thereafter forms gate insulating films and gate electrodes in the trenches. However, in this manufacturing method, impurities in the diffusion layer may be absorbed by the gate insulating films, or the impurities may be discharged from the gate insulating films into the diffusion layer during the formation of the gate insulating films. Due to this, there is a problem that an impurity concentration of the diffusion layer is not stabilized in the semiconductor layer in a vicinity of the trenches (that is, in a vicinity of the gate insulating films), and performance of the insulated gate switching device thereby becomes unstable. With respect to this, there also is a known manufacturing method that forms the trenches first, then forms the gate insulating films and the gate electrodes in the trenches, and thereafter implants the impurities to the semiconductor layer around the trenches to form the diffusion layer. In this manufacturing method, the formation of the gate electrodes is performed by depositing an electrode layer (for example, polysilicon) within the trenches and on a front surface of the semiconductor substrate, the electrode layer on the front surface of the semiconductor substrate is thereafter removed, and unremoved parts of the electrode layer (that is, gate electrodes) is caused to remain within the trenches. In order to remove the electrode layer on the front surface of the semiconductor substrate, the electrode layers (gate electrodes) within the trenches are unnecessarily etched. Thus, an upper end of each gate electrode after the etching is located lower than the front surface of the semiconductor substrate, so a recess is formed at an upper portion of each of the gate electrodes. For example, as shown in FIG. 8, a recess 70 is formed at an upper portion of a gate electrode in each trench 40. As above, if such recesses are present at the upper portions of the gate electrodes, upon the impurity implantation to take place thereafter, the impurities are implanted to undesirably deeper positions locally in the semiconductor layer in the vicinity of the trenches. Notably, FIG. 8 shows an example of implanting the impurities obliquely relative to the semiconductor substrate, however, upon implanting the impurities vertically into the semiconductor substrate as well, such a presence of recesses leads to the implantation of the impurities to undesirably deeper positions locally in the semiconductor layer in the vicinity of the trenches. As above, if the impurities are locally implanted to the deeper positions in the semiconductor layer in the vicinity of the trenches, there is a problem that the impurity concentration does not become uniform in the semiconductor layer in the vicinity of the trenches, and performance of the insulated gate switching device thereby becomes unstable. As above, it is difficult to accurately control the impurity concentration in the semiconductor layer in the vicinity of the trenches in all of the manufacturing methods as aforementioned, and the problem of unstable performance of the insulated gate switching device remains.

WO 2013/121519 A1 discloses a method of manufacturing an insulated gate switching device which attempts to solve the above problem. In this manufacturing method, gate electrodes are formed and impurities are implanted around the gate electrodes as follows. Firstly, trenches are formed on a front surface of a semiconductor substrate. Then, gate insulating films covering inner surfaces of the trenches are formed. Then, an electrode layer is deposited within the trenches and on the front surface of the semiconductor substrate. At this occasion, dents are formed in a front surface of the electrode layer at upper portions of the trenches. Next, the front surface of the electrode layer is polished to thin the electrode layer on the front surface of the semiconductor substrate. The polishing eliminates the dents, and the front surface of the electrode layer is flattened. Then, impurities are implanted in a range extending across the electrode layer in the trenches and the semiconductor substrate. Here, the impurities are implanted from above the flattened front surface. Due to the absence of the dents in the front surface of the electrode layer, the impurities can be implanted in the electrode layer within the trenches and the semiconductor substrate at a uniform depth. Next, the electrode layer on the front surface of the semiconductor substrate (that is, the electrode layer outside the trenches) is removed. The electrode layers remaining in the trenches become gate electrodes. Then, the impurities implanted in the semiconductor substrate is activated by heat treatment. Due to this, a diffusion layer is formed around the trenches. Since the impurities were implanted at the uniform depth in the electrode layers in the trenches and in the semiconductor substrate in the impurity implantation, differences in the impurity concentration in the diffusion layer in the vicinity of the trenches can be suppressed. Then, surface layer portions of the gate electrodes in the trenches are oxidized to form cap insulating films. The cap insulating films are formed so as to prevent compositions of the gate electrodes from diffusing to outsides thereof in oncoming manufacturing processes. The properties of the gate electrodes are prevented from changing by the cap insulating films. The insulated gate switching device is manufactured by thereafter forming other necessary electrodes, insulating films, diffusion layers, and the like. As described above, the manufacturing method of WO 2013/121519 A1 enables impurity implantation at uniform depth in the gate electrodes and the semiconductor layer in the vicinity thereof. Due to this, the impurity concentration of the semiconductor layer in the vicinity of the trenches can accurately be controlled, and differences in the property of insulated gate switching devices can be suppressed.

### SUMMARY

In the technique of WO 2013/121519 A1, the cap insulating films are formed by oxidizing the surface layer portions of the gate electrodes in the trenches after having formed the diffusion layer by implanting the impurities in the semiconductor substrate. Upon oxidizing the surface layer portions of the electrode layers, the semiconductor substrate is subjected to heat treatment. That is, the semiconductor substrate is subjected to heat treatment after having formed the diffusion layer. Due to this, the impurities in the diffusion layer are diffused in the semiconductor substrate during the heat treatment for forming the cap insulating films. As a result of this, the diffusion layer expands by the heat treatment for forming the cap insulating films. Thus, in this manufacturing method, it is difficult to form a small diffusion layer in the semiconductor substrate, which leads to the difficulty in making the insulated gate switching device compact. Due to this, in the present teachings, a manufacturing method that allows an accurate control of an impurity concentration in a semiconductor layer in a vicinity of a trench, and allows an insulated gate switching device to become compact.

A method of manufacturing an insulated gate switching device disclosed herein comprises forming a trench, forming a gate insulating film, depositing an electrode layer, polishing the electrode layer, forming a cap insulating film, and implanting impurities. In the forming of a trench, a trench is formed in a front surface of a semiconductor substrate. In the forming of a gate insulating film, a gate insulating film is formed in the trench. In the depositing of an electrode layer, an electrode layer made of semiconductor is deposited in the trench and on the front surface after forming the gate insulating film. In the polishing of the electrode layer, the electrode layer is polished so as to remove a portion of the electrode layer on the front surface and expose an underlayer of the removed portion of the electrode layer. In the forming of a cap insulating film, a cap insulating film is formed in a surface layer of a portion of the electrode layer in the trench by heating the semiconductor substrate after exposing the underlayer. In the implanting of impurities, impurities are implanted from above the front surface into a range extending across the portion of the electrode layer in the trench and the semiconductor substrate.

Notably, in the deposition of the electrode layer (that is, depositing the electrode layer on the front surface of the semiconductor substrate), the electrode layer may be deposited directly on the front surface of the semiconductor substrate, or another layer (for example, an insulating layer) may be formed on the front surface of the semiconductor substrate and the electrode layer may be deposited thereon. Further, the underlayer as above means a layer formed underneath the electrode layer. The underlayer may be a layer that is in direct contact with the electrode layer, or may be one of layers that are underneath the layer making direct contact with the electrode layer. Further, the underlayer may be the semiconductor substrate itself.

In this manufacturing method, the electrode layer is polished after the electrode layer has been deposited on the front surface of the semiconductor substrate. Upon the polishing, the portion of the electrode layer on the front surface of the semiconductor substrate is removed and the underlayer thereof is exposed. Due to this, the front surface of the electrode layer remaining in the trench and a front surface of the underlayer configure one flat surface after the polishing. The portion of the electrode layer remaining in the trench is the gate electrode. Next, a surface layer portion of the electrode layer in the trench (that is, the front surface exposed therein) is oxidized by subjecting the semiconductor substrate to heat treatment. The cap insulating film is thereby formed. Since the front surface of the electrode layer and the front surface of the underlayer configure one flat surface prior to the formation of the cap insulating film, a front surface of the cap insulating film and the front surface of the underlayer similarly configure one flat surface. Then, the impurities are implanted from above the front surface of the semiconductor substrate (that is, from the front surface side that had been polished) into the electrode layer and the semiconductor substrate. Since the front surface of the cap insulating film and the front surface of the underlayer configure one flat surface, the impurities can be implanted at a uniform depth in the electrode layer and the semiconductor substrate. That is, an impurity implanting depth can be suppressed from becoming locally deep in a vicinity of the trench. Thus, by implanting the impurities as above, the impurity concentration in the semiconductor layer in the vicinity of the trench can accurately be controlled. According to this manufacturing method, differences in property of insulated gate switching devices can be suppressed. Further, since the impurities are implanted after having formed the cap insulating film, the impurities that were implanted do not diffuse by an influence of the heat treatment for forming the cap insulating film. Due to this, the impurities that were implanted are suppressed from diffusing at a greater degree than needed. Thus, according to this manufacturing method, a size reduction of the insulated gate switching device can be achieved.

### BRIEF DESCRIPTION OF DRAWINGS

FIG. 1 is a vertical cross sectional view of an IGBT 10 (it is a vertical cross sectional view along line I-I in FIG. 2);

FIG. 2 is a plan view of a front surface 12a of a semiconductor substrate 12;

FIG. 3 is an explanatory diagram of formation of an insulating film 42;

FIG. 4 is an explanatory diagram of formation of an electrode layer 52;

FIG. 5 is an explanatory diagram of polishing;

FIG. 6 is an explanatory diagram of formation of cap insulating films 46;

FIG. 7 is an explanatory diagram of an ion implantation of an embodiment;

FIG. 8 is an explanatory diagram of an ion implantation of a comparative example;

FIG. 9 is a plan view showing a mask layer 50;

FIG. 10 is an explanatory diagram of formation of an interlayer insulating film 47;

FIG. 11 is an explanatory diagram of polishing in a variant;

FIG. 12 is an explanatory diagram of formation of cap insulating films 46 in a variant;

FIG. 13 is a plan view of an IGBT of a variant corresponding to FIG. 2;

FIG. 14 is a vertical cross sectional view along line A-A in FIG. 13; and

FIG. 15 is a vertical cross sectional view along line B-B in FIG. 13.

### DETAILED DESCRIPTION

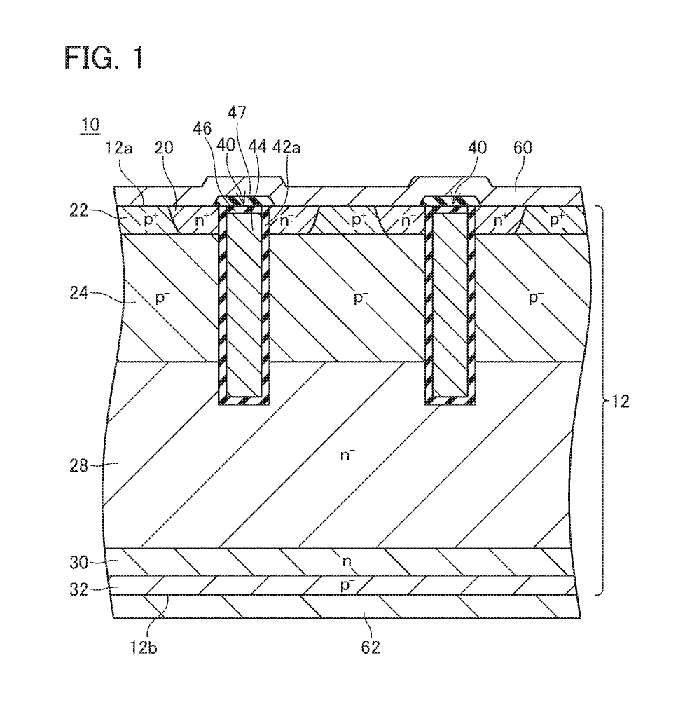

An IGBT 10 of an embodiment shown in FIG. 1 comprises a semiconductor substrate 12 configured of a single crystal silicon, an emitter electrode 60 provided on a front surface 12a of the semiconductor substrate 12, and a collector electrode 62 provided on a back surface 12b of the semiconductor substrate 12.

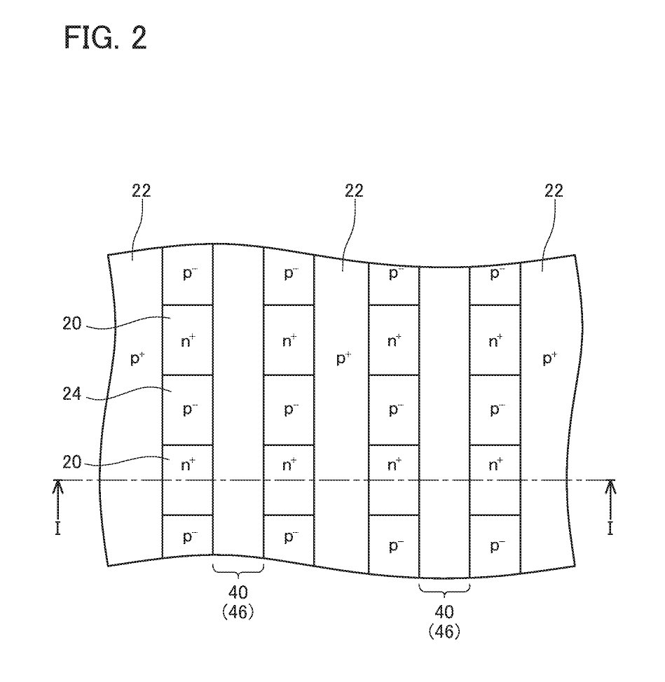

A plurality of trenches 40 is provided on the front surface 12a of the semiconductor substrate 12. As shown in FIG. 2, when the front surface 12a of the semiconductor substrate 12 is seen in a plan view, the trenches 40 extend parallel to each other. As shown in FIG. 1, an inner surface of each trench 40 is covered by a gate insulating film 42a. A gate electrode 44 is provided inside each trench 40. The gate electrodes 44 are configured of p-type polysilicon having an electric resistance adjusted to be relatively low. The gate electrodes 44 are insulated from the semiconductor substrate 12 by the gate insulating films 42a. A front surface of each gate electrode 44 is covered by a cap insulating film 46. An interlayer insulating film 47 is provided on each cap insulating film 46. The gate electrodes 44 are insulated from the emitter electrode 60 by the cap insulating films 46 and the interlayer insulating films 47. The gate electrodes 44 are configured capable of connecting to outside at positions that are not shown.

Emitter regions 20, a body contact region 22, a body region 24, a drift region 28, a buffer region 30, and a collector region 32 are provided inside the semiconductor substrate 12.

The emitter regions 20 are n-type regions, and are exposed on the front surface 12a of the semiconductor substrate 12. The emitter regions 20 make contact with a corresponding gate insulating film 42a. As shown in FIG. 2, the emitter regions 20 are provided in plurality at positions making contact with the trenches 40 (that is, the gate insulating films 42a). Each emitter region 20 makes an ohmic contact with the emitter electrode 60.

The body contact region 22 is a p-type region with a high p-type impurity concentration. The body contact region 22 is provided at a position separate from the gate insulating films 42a. The body contact region 22 is exposed on the front surface 12a of the semiconductor substrate 12. The body contact region 22 makes an ohmic contact with the emitter electrode 60.

The body region 24 is a p-type region with a p-type impurity concentration lower than that of the body contact region 22. The body region 24 is provided under the emitter regions 20 and the body contact region 22 (back surface 12b side). The body region 24 makes contact with the gate insulating films 42a under the emitter regions 20. Further, as shown in FIG. 2, the body region 24 is exposed on the front surface 12a of the semiconductor substrate 12 in between two adjacent emitter regions 20. The body region 24 makes contact with the emitter electrode 60.

The drift region 28 is an n-type region that contains n-type impurities at a lower concentration than the emitter regions 20. The drift region 28 is provided under the body region 24. The drift region 28 is separated from the emitter regions 20 by the body region 24. The drift region 28 makes contact with the gate insulating films 42a under the body region 24.

The buffer region 30 is an n-type region that contains the n-type impurities at a higher concentration than the drift region 28. The buffer region 30 is provided under the drift region 28.

The collector region 32 is a p-type region containing p-type impurities at a high concentration. The collector region 32 is provided under the buffer region 30. The collector region 32 is exposed on the back surface 12b of the semiconductor substrate 12. The collector region 32 makes ohmic contact with the collector electrode 62. The collector region 32 is separated from the body region 24 by the drift region 28 and the buffer region 30.

Upon the operation of the IGBT 10, a voltage that charges the collector electrode 62 to be positive is applied between the emitter electrode 60 and the collector electrode 62. Moreover, the IGBT 10 turns on when a voltage that is equal to or more than a gate threshold is applied to the gate electrodes 44. That is, when the voltage that is equal to or more than the gate threshold is applied to the gate electrodes 44, channels are formed in the body region 24 in a vicinity of the gate insulating films 42a. Then, electrons flow from the emitter regions 20 to the collector region 32 through the channels, the drift region 28, and the buffer region 30. At the same time, holes flow from the collector region 32 to the body contact region 22 through the buffer region 30, the drift region 28, and the body region 24. Due to this, a current flows through the IGBT 10.

As described above, the body region 24 in the vicinity of the trenches 40 (that is, vicinity of the gate insulating films 42a) is the region where the channels are formed upon when the IGBT 10 turns on. Due to this, when the p-type impurity concentration of the body region 24 in the vicinity of the trenches 40 is high, the channels are not formed easily and a gate threshold becomes high. That is, a gate threshold changes according to the p-type impurity concentration of the body region 24 in the vicinity of the trenches 40. Further, when the p-type impurity concentration of the body region 24 in the vicinity of the trenches 40 is high, a resistance for the electrons passing through the channels (hereinbelow referred to as channel resistance) becomes large. That is, the channel resistance changes according to the p-type impurity concentration of the body region 24 in the vicinity of the trenches 40. Due to this, differences will be generated in the gate threshold and the ON voltage among the mass-produced IGBTs 10 if the p-type impurity concentration of the body region 24 in the vicinity of the trenches 40 is not controlled accurately upon manufacturing the IGBTs 10. Further, if sizes of the emitter regions 20 and the body region 24 in a depth direction are not controlled accurately upon manufacturing the IGBTs 10, differences will be generated in channel lengths, and differences will be generated in the gate threshold and the ON voltage among the mass-produced IGBTs 10. A manufacturing method of the IGBT 10 of the present embodiment suppresses the differences in the property of the IGBTs 10 by suppressing the differences in the impurity concentration of the body region 24 and the emitter regions 20 in the vicinity of the trenches 40 and the differences in the impurity implanting depths. Detailed description will be given hereinbelow.

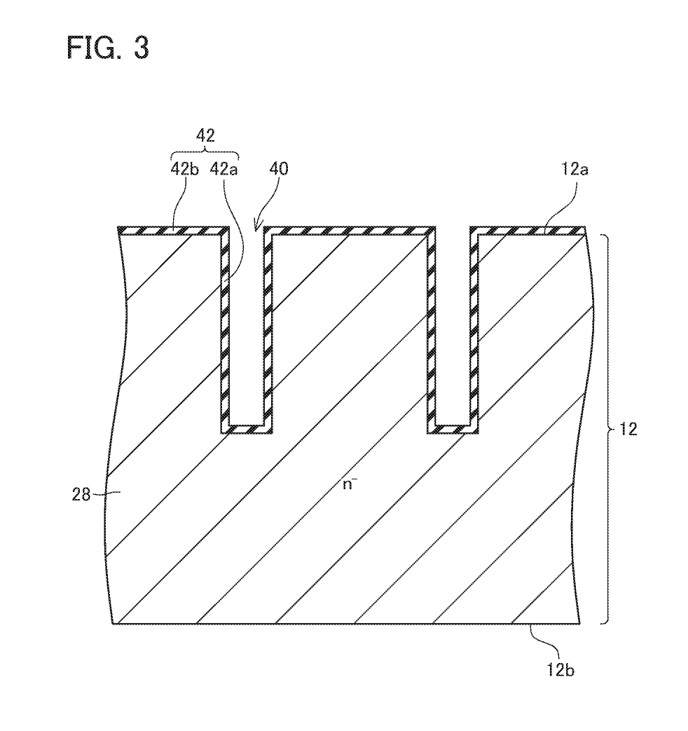

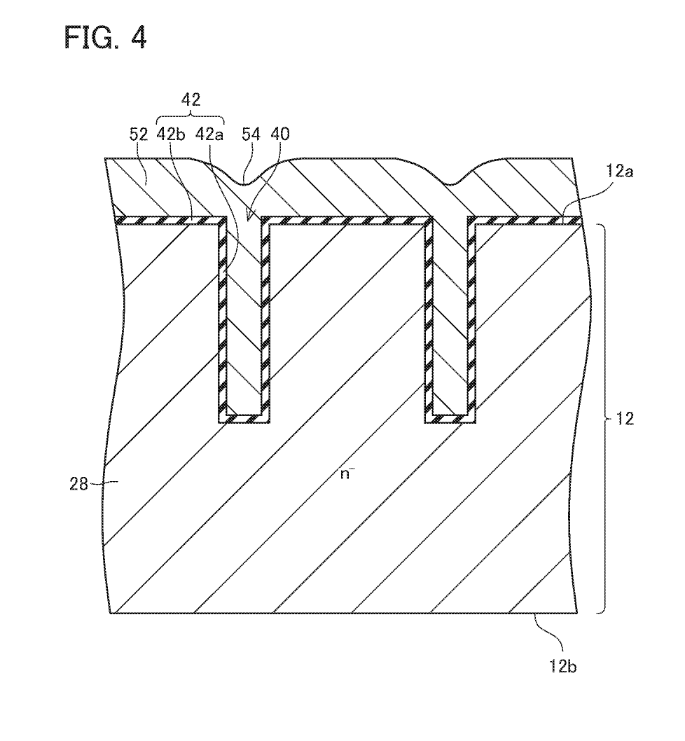

The IGBT 10 is manufactured from an n-type semiconductor substrate having substantially the same n-type impurity concentration as the drift region 28 (semiconductor substrate 12 before processing). Firstly, selective etching is performed on the semiconductor substrate 12 to form the trenches 40. Then, as shown in FIG. 3, the semiconductor substrate 12 is oxidized to form an insulating film 42. The insulating film 42 is formed on inner surfaces of the trenches 40 and on the front surface 12a of the semiconductor substrate 12. The insulating film 42 formed on the inner surface of each trench 40 is the gate insulating film 42a. Further, hereinbelow, the insulating film 42 formed on the front surface 12a of the semiconductor substrate 12 will be called the front surface insulating film 42b. Next, as shown in FIG. 4, an electrode layer 52 configured of p-type polysilicon is deposited on the front surface 12a of the semiconductor substrate 12 and the inner surfaces of the trenches 40 by using a PVD method or a CVD method. The electrode layer 52 is deposited without any gap within the trenches 40. Further, a dent 54 is formed on a front surface of the electrode layer 52 above each of the trenches 40 by an influence of a shape of the trenches 40.

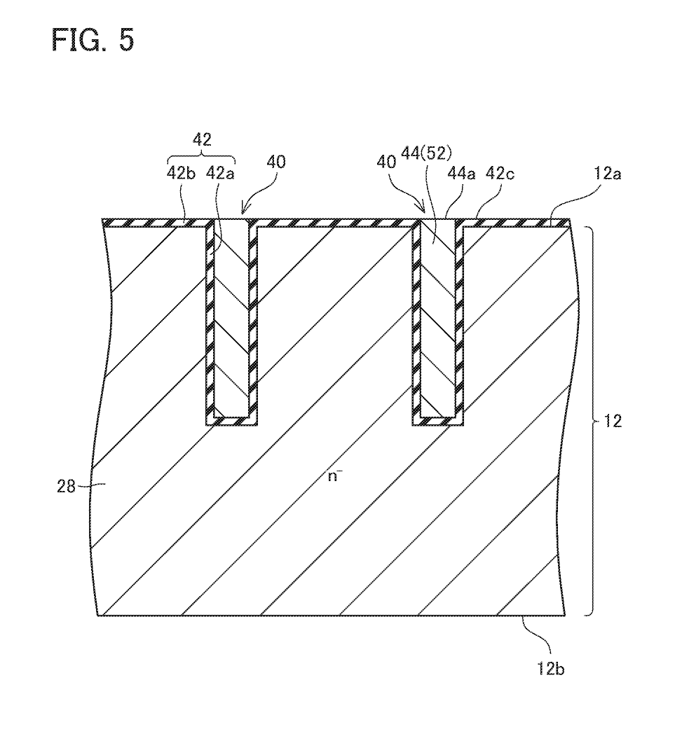

Next, the front surface of the electrode layer 52 is polished by CMP (Chemical Mechanical Polishing). Here, as shown in FIG. 5, the electrode layer 52 is polished until the front surface insulating film 42b thereunder is exposed. That is, a portion of the electrode layer 52 on the front surface 12a is removed by the polishing. A portion of the electrode layer 52 is left remaining within the trenches 40. The portion of the electrode layer 52 remaining in each trench 40 is the gate electrode 44. As above, when the portion of the electrode layer 52 on the front surface 12a is removed, a flat surface is formed by front surfaces 44a of the gate electrodes 44 and a front surface 42c of the front surface insulating film 42b. In other words, the front surfaces 44a of the gate electrodes 44 and the front surface 42c of the front surface insulating film 42b come to be in a state of being disposed on the same plane. No level differences, or surface roughness exists over the front surfaces 44a of the gate electrodes 44 to the front surface 42c of the front surface insulating film 42b.

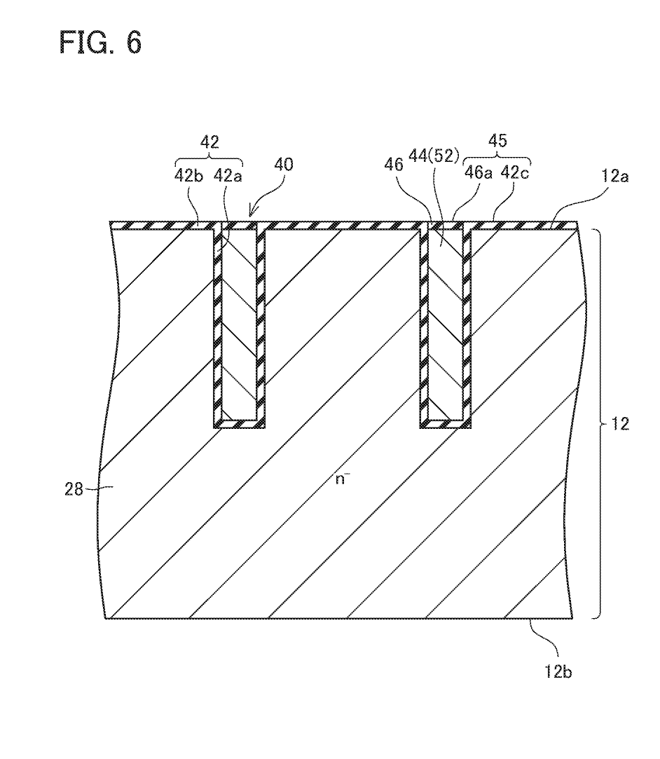

Next, the front surfaces 44a of the gate electrodes 44 are oxidized by heat treating the semiconductor substrate 12 under an oxygen atmosphere. Due to this, as shown in FIG. 6, the cap insulating films 46 are formed on the surface layer portions of the gate electrodes 44. The cap insulating films 46 prevent the p-type impurities contained in the gate electrodes 44 from diffusing to outside of the semiconductor substrate 12 in following steps. Due to this, conductivity of the gate electrodes 44 is prevented from being reduced. The gate electrodes 44 (that is, polysilicon) experiences volume expansion upon oxidization, however, an expanding amount thereof is scarce. Thus, positions of front surfaces 46a of the cap insulating films 46 hardly change from positions of the front surfaces 44a of the gate electrodes 44 before the oxidization. Due to this, a flat surface is formed by the front surfaces 46a of the cap insulating films 46 and the front surface 42c of the front surface insulating film 42b. Hereinbelow, a flat front surface formed by the front surfaces 46a of the cap insulating films 46 and the front surface 42c of the front surface insulating film 42b will be termed a front surface 45.

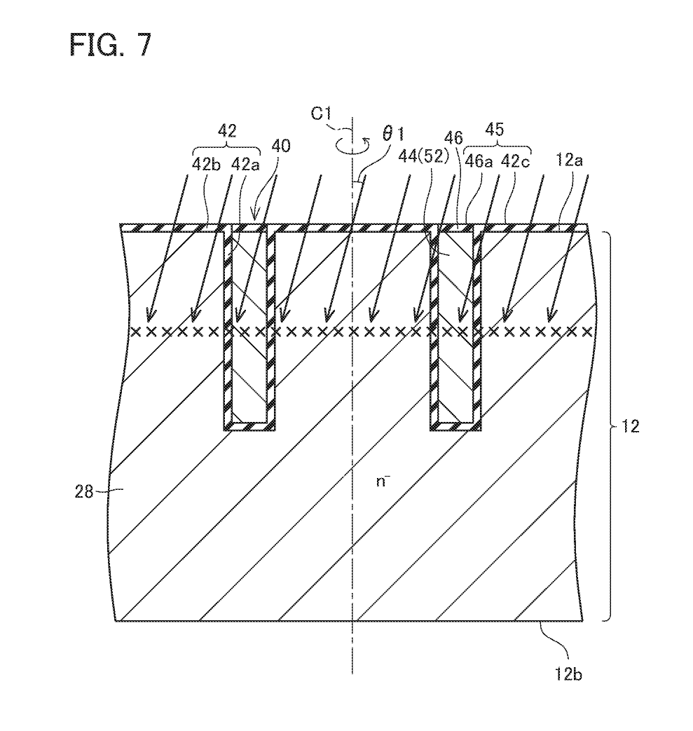

Next, ion implantation to the body region 24 is performed. Here, firstly, a mask is formed on a front surface on an outer circumferential portion of the semiconductor substrate 12 that is not shown. The mask is not formed in a range where the body region 24 is to be formed. That is, in the range where the body region 24 is to be formed, the cap insulating films 46 and the front surface insulating film 42b are exposed. Then, as shown in FIG. 7, the p-type impurities are implanted to the semiconductor substrate 12 from above the front surface 12a (that is, front surface 45) while rotating the semiconductor substrate 12 about its center axis C1. The center axis C1 is parallel to a thickness direction of the semiconductor substrate 12, and is located at a center of the semiconductor substrate 12 when the semiconductor substrate 12 is seen in a plan view. Here, the p-type impurities are implanted with a certain angle θ1 formed between the center axis C1 (that is, thickness direction of the semiconductor substrate 12) and an impurities implanting direction. Here, the p-type impurities are implanted not only to the semiconductor substrate 12 but also to the gate electrodes 44. The p-type impurities are implanted at a certain distance (depth) from the front surface 45. Since the front surface 45 is flat, the p-type impurities are implanted to the semiconductor substrate 12 and the gate electrodes 44 at substantially the same depth. That is, the p-type impurities are implanted in a range across the semiconductor substrate 12 and the gate electrodes 44 at a substantially constant depth.

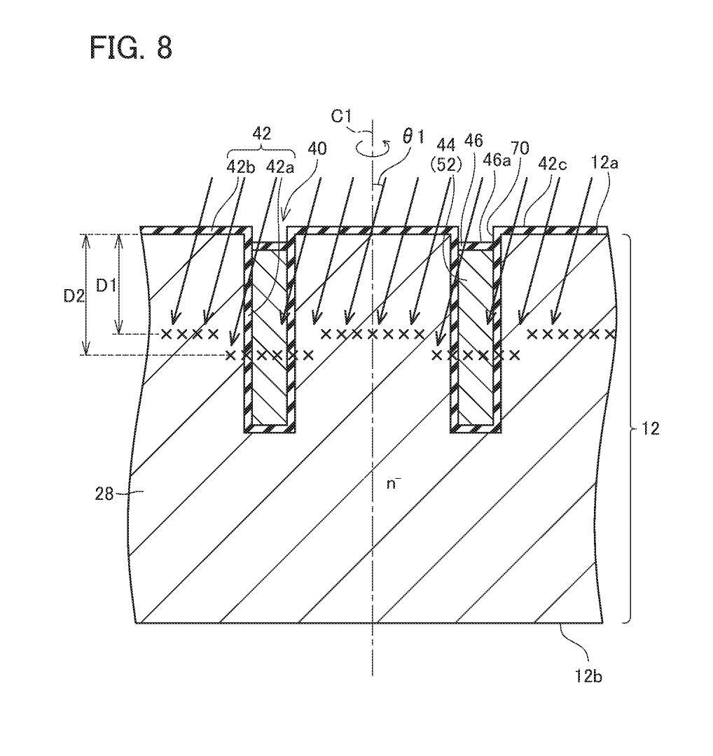

FIG. 8 shows an ion implanting process of a comparative example. In FIG. 8, the front surfaces 46a of the cap insulating films 46 are located lower than the front surface 12a of the semiconductor substrate 12. That is, dents 70 are formed at upper portions of the trenches 40. Such a configuration is obtained when a portion of the electrode layer 52 on the front surface 12a formed as in FIG. 4 is removed by etching. Aside from the point that the dents 70 are formed, the ion implanting process of FIG. 8 is same as an ion implanting process of FIG. 7. In the ion implanting process of FIG. 8, an implanted depth D2 of the p-type impurities having entered the semiconductor substrate 12 through the cap insulating films 46 in the dents 70 becomes deeper than an implanted depth D1 of the p-type impurities having entered the semiconductor substrate 12 through the front surface insulating film 42b. Since the semiconductor substrate 12 is rotating, the implanted depth becomes deep in the semiconductor layer on both sides of each trench 40. Accordingly, in the ion implanting process of FIG. 8, the implanted depths of the impurities do not become uniform like the ion implanting process of FIG. 7. In the ion implanting process of FIG. 8, the implanted depth of the impurities become locally deep in the vicinity of each trench 40. When the implanted depth of the impurities is locally deep in the vicinity of each trench 40, a p-type impurity concentration distribution changes according to the implanted depths thereof. Moreover, the implanted depth of the impurities in the vicinity of each trench 40 changes depending on a depth of the dents 70. Since the depths of the dents 70 cannot be controlled accurately, differences in the impurities implanted depth in the vicinity of the trenches 40 become large. Thus, due to the differences in the impurities implanted depth in the vicinity of the trenches 40, the differences in the p-type impurity concentration distribution in the vicinity of the trenches 40 become large. As above, in the ion implanting process of FIG. 8, the differences in the implanted depth of the p-type impurities and the differences in the p-type impurity concentration in the vicinity of the trenches 40 become large. Due to this, the differences in the gate threshold and the ON voltage among the manufactured IGBTs become large.

Contrary to this, in the ion implanting process of the present embodiment as shown in FIG. 7, the impurity implanted depth does not become locally deep in the vicinity of the trenches 40, since the front surfaces 46a of the cap insulating films 46 and the front surface 42c of the front surface insulating film 42b are present on the substantially same plane. Due to this, the differences are less likely to be generated in the p-type impurity implanted depth and the p-type impurity concentration in the vicinity of the trenches 40. According to this method, the differences in the gate threshold and the ON voltage among the manufactured IGBTs 10 can be suppressed.

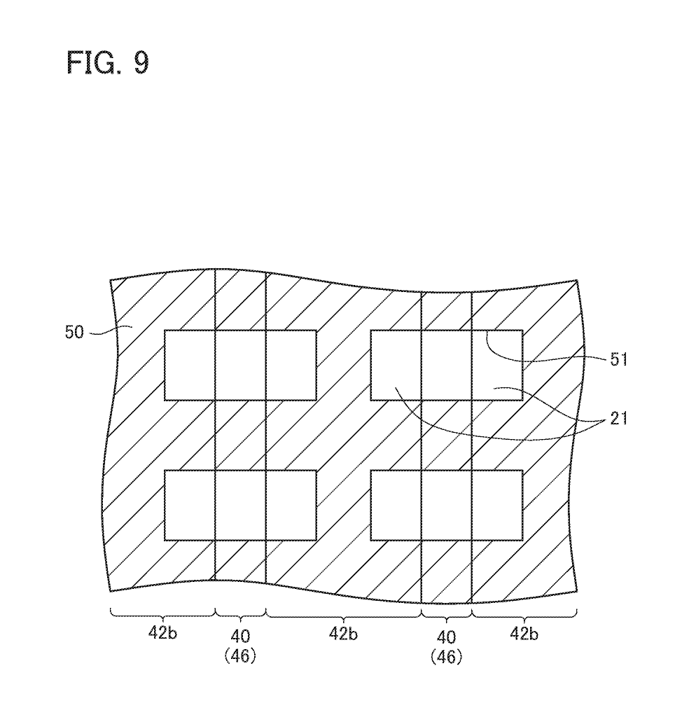

When the ion implantation to the body region 24 has been performed, then an ion implantation to the emitter regions 20 is performed. Here, as shown in FIG. 9, a mask layer 50 is formed on the front surface 45. In FIG. 9, a hatched region denotes a region covered by the mask layer 50. The mask layer 50 includes openings 51. The openings 51 are arranged above regions 21 where the emitter regions 20 are to be formed and the cap insulating films 46 intervened between the adjacent ranges 21. That is, a contour of each opening 51 (that is, an edge of mask layer 50) extends so as to encompass the front surface 46a of the cap insulating film 46 and the front surface 42c of the front surface insulating film 42b. In other words, the contour of each opening 51 is arranged to traverse across the trench 40. The cap insulating films 46 and the front surface insulating film 42b are exposed in the openings 51. The mask layer 50 as above (that is, the mask layer 50 in which contours of the openings 51 traverse across the trenches 40) cannot be formed highly accurately on a front surface having surface roughness (for example, the dents 70 in FIG. 8 or the like). With respect to this, in the method of the present embodiment, since there is no surface roughness formed on the front surface 45, the mask layer 50 can be formed highly accurately. After the formation of the mask layer 50, n-type impurities are implanted to the semiconductor substrate 12 from above the front surface 12a of the semiconductor substrate 12 (that is, from a front surface 45 side) through the mask layer 50. Here, similar to the ion implantation in the body region 24, the n-type impurities are implanted by tilting its implanting direction relative to the rotation axis while rotating the semiconductor substrate 12. Since the mask layer 50 stops the n-type impurities, the n-type impurities are not implanted in the semiconductor substrate 12 in the range covered by the mask layer 50. The n-type impurities are implanted in the semiconductor substrate 12 within the openings 51. Since the mask layer 50 is formed highly accurately, an implantation range of the n-type impurities is controlled highly accurately. Further, in the implantation of the emitter regions 20 as well, similar to the implantation of the body region 24, differences in the implanted depth and the differences in the impurity concentration in the vicinity of the trenches 40 are suppressed. Due to this as well, the differences in the gate threshold and the ON voltage among the manufactured IGBTs 10 can be suppressed.

After the ion implantation to the emitter regions 20 has been performed, then, an ion implantation to the body contact region 22 is performed. That is, a mask layer corresponding to the body contact region 22 is formed on the front surface 45, and the p-type impurities are implanted to the semiconductor substrate 12 through the mask layer.

After when the ion implantation to the body contact region 22 has been performed, the impurities implanted in the semiconductor substrate is diffused and activated by subjecting the semiconductor substrate 12 to heat treatment. Due to this, the emitter regions 20, the body contact region 22, and the body region 24 are formed within the semiconductor substrate 12. This heat treatment is performed by controlling temperature and time so that the impurities are effectively activated and diffused to desired ranges. Thus, the impurities are prevented from being diffused greater than needed.

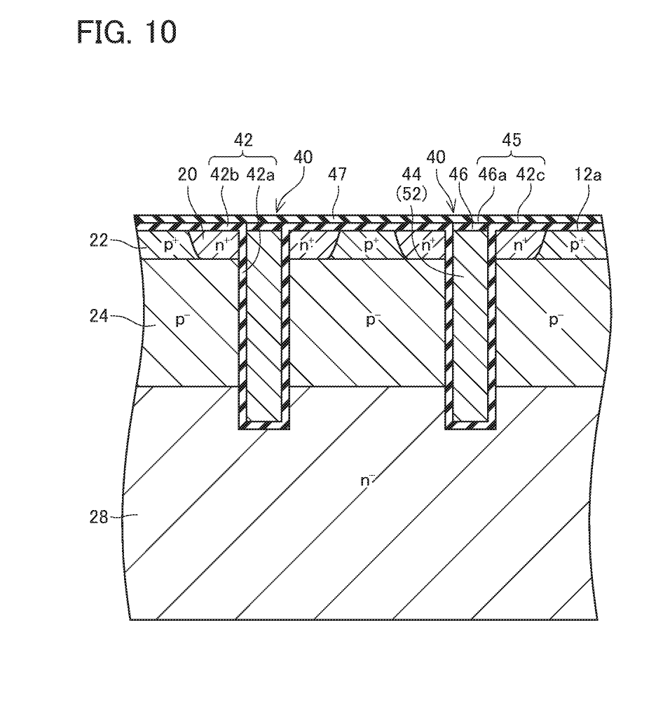

Next, as shown in FIG. 10, the interlayer insulating film 47 is formed on the front surface 45. The interlayer insulating film 47 is an NSG (Non-doped Silicon Glass) film. The interlayer insulating film 47 is formed over an entire region of the front surface 45. That is, the interlayer insulating film 47 is formed so as to extend across the front surfaces 46a of the cap insulating films 46 and the front surface 42c of the front surface insulating film 42b. In general, the NSG film cannot be formed uniformly on a front surface having surface roughness. If the NSG film is formed on the front surface having surface roughness, voids and the like are likely to occur in the NSG film. Thus, in many of the cases of forming an insulating film on the front surface having surface roughness, a BPSG (Boron Phosphor Silicate Glass) film is formed first, and then the NSG film is formed on the BPSG film. With respect to this, in the present embodiment, since the front surface 45 is flat, the NSG film (that is, interlayer insulating film 47) can be formed directly on the front surface 45. Due to the lack of need to form the BPSG film, the interlayer insulating film 47 can be formed efficiently.

Next, the interlayer insulating film 47 is left remaining on the trenches 40, and the interlayer insulating film 47 other than the aforementioned remaining parts and the front surface insulating film 42b are removed by etching. Due to this, the front surface 12a of the semiconductor substrate 12 (that is, emitter regions 20, body contact region 22, and body region 24) are exposed. Then, as shown in FIG. 1, the emitter electrode 60 is formed on the front surface 12a of the semiconductor substrate 12. Then, impurities are implanted on the back surface 12b of the semiconductor substrate 12, and the buffer region 30 and the collector region 32 are formed by locally subjecting the region on the back surface 12b of the semiconductor substrate 12 to heat treatment using laser annealing. Then, the collector electrode 62 is formed on the back surface 12b of the semiconductor substrate 12. The IGBT 10 is completed by the above processes.

As described above, in this manufacturing method, the portion of the electrode layer 52 on the front surface 12a is removed by polishing after having deposited the portion of the electrode layer 52 in the trenches 40 and on the front surface 12a of the semiconductor substrate 12. Thus, after the polishing, the front surface configured of the front surfaces 44a of the gate electrodes 44 in the trenches 40 and the front surface 42c of the front surface insulating film 42b becomes extremely flat. Due to this, the front surface 45 is flat even after the formation of the cap insulating films 46. In the impurity implantations for the body region 24 and the emitter regions 20, the implanted depth of the impurities in the gate electrodes 44 and the semiconductor substrate 12 becomes substantially the same, since the impurities are implanted into the gate electrodes 44 and the semiconductor substrate 12 from above the flat front surface 45. Due to this, the implanted depth can be prevented from becoming locally deep in the vicinity of the trenches 40. Thus, the implanted depth and the impurity concentration in the vicinity of the trenches 40 can be stabilized. That is, the differences in the p-type impurity concentration of the body region 24 in the vicinity of the trenches 40, the position of the body region 24 in the depth direction in the vicinity of the trenches 40, the n-type impurity concentration of the emitter regions 20 in the vicinity of the trenches 40, and the position of the emitter regions 20 in the depth direction in the vicinity of the trenches 40 can be suppressed. Thus, according to this manufacturing method, the differences in the gate threshold and the ON voltage among the manufactured IGBTs 10 can be suppressed.

Further, in this method, the impurities are implanted in the semiconductor substrate 12 after the cap insulating films 46 have been formed. The impurities implanted in the semiconductor substrate 12 do not experience the heat treatment for forming the cap insulating films 46. Due to this, the impurities can be prevented from diffusing in the semiconductor substrate 12 due to the heat treatment for forming the cap insulating films 46. That is, in this method, a number of processes in which the semiconductor substrate 12 is exposed to heat after the impurity implantations can be reduced. Due to this, the emitter regions 20, the body contact region 22, and the body region 24 can be formed compact. Notably, the heat treatment for activating the impurities after the impurities implantation is performed by controlling the temperature and the time so that the impurities are effectively activated and diffused to the desired range. Thus, in this heat treatment as well, the impurities can be prevented from diffusing greater than needed.

Relationship of the aforementioned constituent features of the embodiment and the constituent features of the claims will be described. The gate electrodes 44 of the embodiment are an example of “an electrode layer” in “a trench” in the claims. The front surface insulating film 42b of the embodiment is an example of “an underlayer” in the claims. The implantation of the p-type impurities to the body region 24 of the embodiment is an example of “implanting impurities” in the claims. Further, the implantation of the n-type impurities to the emitter regions of the embodiment is also an example of the “implanting impurities” in the claims. The mask layer 50 of the embodiment is an example of a “mask layer” in the claims. The interlayer insulating films 47 of the embodiment are an example of “an NSG film” in the claims.

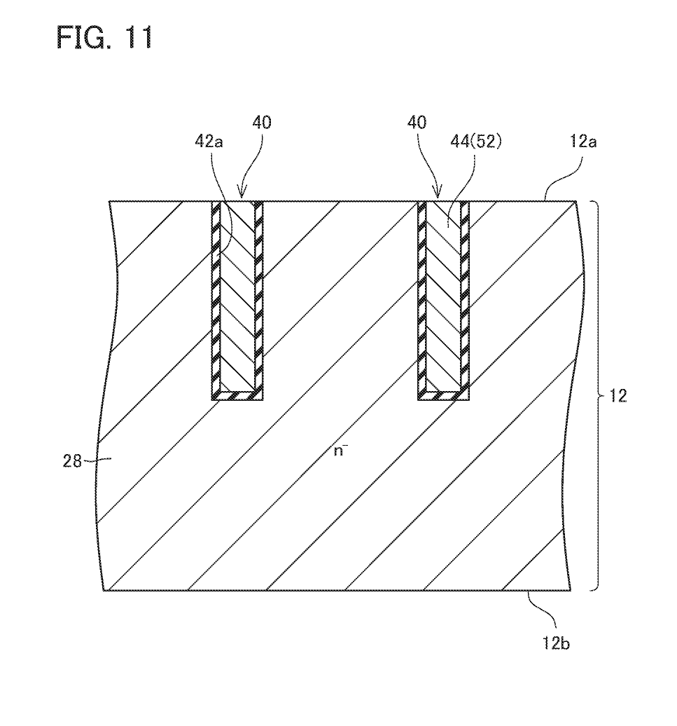

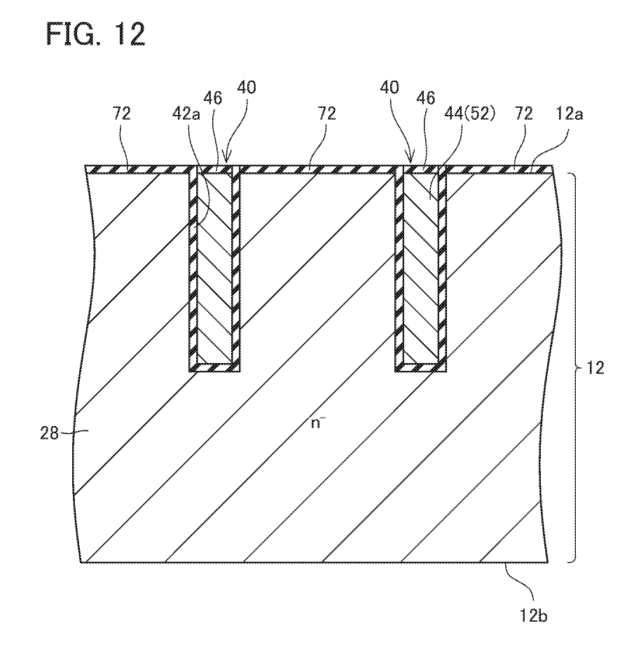

Notably, in the above embodiment, the front surface insulating film 42b was exposed by polishing. However, as shown in FIG. 11, the front surface insulating film 42b may be removed in the polishing, and the semiconductor substrate 12 may be exposed. In this case, when the cap insulating films 46 are to be formed thereafter, the insulating film 72 is formed also on the surface layer portion of the semiconductor substrate 12 as shown in FIG. 12. The structure shown in FIG. 12 is substantially equivalent to the structure shown in FIG. 6. Thus, subsequent processes can be performed similar to those of the above embodiment. Notably, in this case, the semiconductor substrate 12 is an example of the “underlayer” of the claims.

Further, in the above embodiment, a manufacturing process for IGBTs was described. However, the technique disclosed herein may be adapted to a manufacturing process for MOSFETs. In the IGBT 10 of FIG. 1, MOSFET can be configured by replacing the collector region 32 with a high concentration n-type region (drain region). In the manufacturing process for the MOSFETs as well, the implanted depth and the impurity concentration in the vicinity of the trenches can be stabilized, and differences in gate threshold and ON resistance of the MOSFETs can be suppressed.

Further, in the above embodiment, the case in which the impurities are implanted obliquely relative to the semiconductor substrate 12 was described. That is, the impurities were implanted with the angle θ1 formed between the center axis C1 of the semiconductor substrate 12 (thickness direction) and the ion implanting direction. However, the technique disclosed herein may be adapted to a case of implanting the impurities vertical to the semiconductor substrate (that is, the case where the ion implanting direction is parallel to the thickness direction). Even in the case of implanting the impurities vertical to the semiconductor substrate, the impurity implanted depth becomes locally deep in the semiconductor layer in the vicinity of the trenches 40 if the dents 70 are formed at the upper portions of the trenches 40 as in FIG. 8. Thus, even in the case of implanting the impurities vertical to the semiconductor substrate, the impurity implanted depth can be prevented from becoming locally deep in the semiconductor layer in the vicinity of the trenches 40 by the technique disclosed herein.

Further, in the above embodiment, the electrode layer 52 (that is, gate electrodes 44) was configured of polysilicon. However, the electrode layer 52 may be made of other semiconductor materials.

Further, in the above embodiment, the semiconductor substrate 12 was configured of silicon, however, the semiconductor substrate 12 may be configured of other semiconductor materials, such as SiC. Notably, in a case where the electrode layer 52 is polysilicon and the semiconductor substrate 12 is SiC, there is a difference in a resistance relative to the impurities to be implanted (that is, a function to stop the impurities that are being implanted) between the electrode layer 52 and the semiconductor substrate 12. Due to this, as compared to the aforementioned embodiment, the difference in the implanted depth relative to the electrode layer 52 in the trenches 40 and the implanted depth relative to the semiconductor substrate 12 becomes larger. However, even in this case, the impurities can be implanted at a uniform depth, as compared to the case of implanting the impurities in the state where the dents 70 are formed as in FIG. 8. Further, since polysilicon and SiC are both semiconductor materials, there is not such a large difference in their resistances to the impurities to be implanted. Thus, the aforementioned difference in the implanted depths does not become so large. Due to this, even in this case, the impurity concentration of the semiconductor layer in the vicinity of the trenches can be controlled accurately.

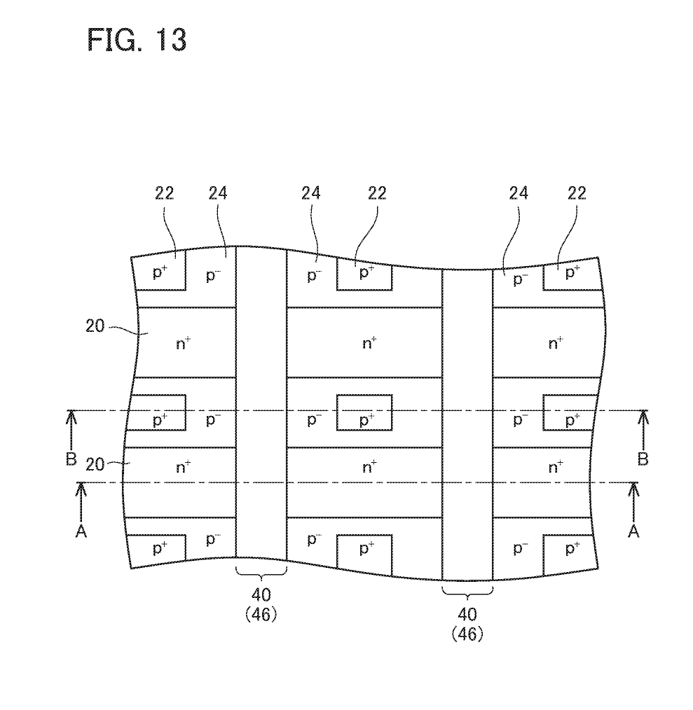

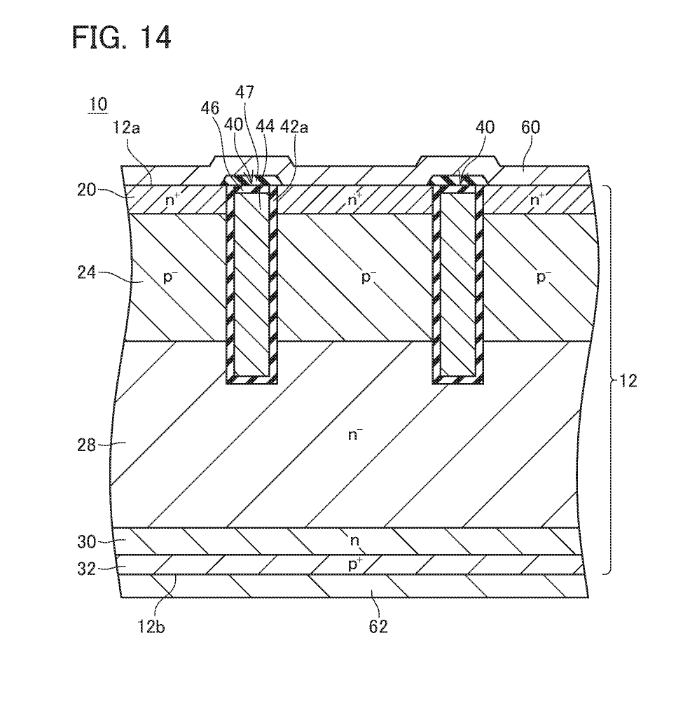

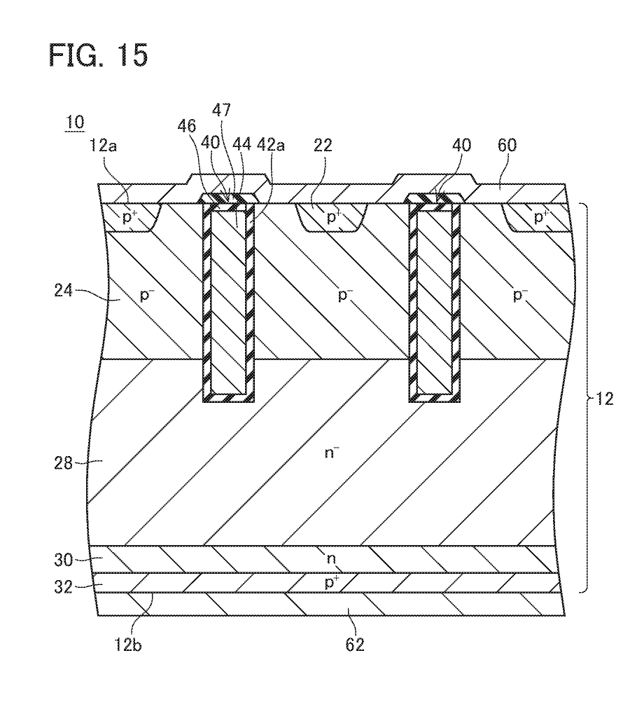

Further, the semiconductor regions may be arranged differently from the aforementioned embodiment. For example, as shown in FIGS. 13 to 15, the arrangements of the emitter regions 20, the body contact region 22, and the body region 24 may be changed. In these embodiments, as shown in FIG. 13, the plurality of emitter regions 20 extends linearly in a direction perpendicularly intersecting the trenches 40 in the front surface 12a of the semiconductor substrate 12. The body region 24 and the body contact region 22 are exposed at interval portions between the emitter regions 20. As shown in FIGS. 14 and 15, the body region 24 is formed also under the emitter regions 20 and the body contact region 22. Thus, the emitter regions 20 and the body contact region 22 are separated from the drift region 28 by the body region 24. The drift region 28, the buffer region 30, and the collector region 32 are formed similar to FIG. 1. In the semiconductor device shown in FIGS. 13 to 15 as well, the impurities implanted depth and the impurity concentration in the semiconductor regions in the vicinity of the trenches 40 can be controlled accurately by using a similar manufacturing method to the aforementioned embodiment. Further, the implanted impurities can be prevented from diffusing greater than needed.

Some of the technical elements disclosed in this disclosure will be listed below. Notably, each of the technical elements below has independent utility.

A manufacturing method disclosed herein as an example may further comprise forming a mask layer having an opening, an outline of the opening extending across a surface of the cap insulating film and a surface of the underlayer. In this case, the impurities may be implanted via the mask layer in the implantation of the impurities.

According to this configuration, since the front surface of the substrate is flat, the mask layer can be formed more accurately. Thus, the implanted range of the impurities can be controlled at high accuracy.

A manufacturing method disclosed herein as an example may further comprise forming an NSG film extending across a surface of the cap insulating film and a surface of the underlayer after implanting the impurities into the range extending across the portion of the electrode layer in the trench and the semiconductor substrate.

According to this configuration, since the front surface of the substrate is flat, the NSG film can suitably be formed.

Specific examples of the present disclosure has been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A method of manufacturing an insulated gate switching device, the method comprising:
forming a trench in a front surface of a semiconductor substrate;
forming a gate insulating film in the trench;
depositing an electrode layer made of a semiconductor material in the trench and on the front surface of the semiconductor substrate after forming the gate insulating film;
polishing the electrode layer so as to remove a portion of the electrode layer on the front surface of the semiconductor substrate and expose an underlayer of the removed portion of the electrode layer;
forming a cap insulating film in a surface layer of a portion of the electrode layer in the trench by heating the semiconductor substrate after exposing the underlayer; and
implanting impurities from above the front surface into a range extending across the portion of the electrode layer in the trench and the semiconductor substrate.

2. The method of claim 1, further comprising forming a mask layer having an opening, an outline of the opening extending across a surface of the cap insulating film and a surface of the underlayer, wherein the impurities are implanted via the mask layer in the implantation of the impurities.

3. The method of claim 1, further comprising forming an NSG film extending across a surface of the cap insulating film and a surface of the underlayer after implanting the impurities into the range extending across the portion of the electrode layer in the trench and the semiconductor substrate.

4. The method of claim 3, wherein the NSG film is formed directly on the surface of the cap insulating film and the surface of the underlayer.
